(19) United States
(12) Patent Application Publication
(10) Pub. No.: US 2026/0090225 A1
(43) Pub. Date: Mar. 26, 2026

(54) DISPLAY DEVICE, ELECTRONIC DEVICE AND METHOD OF FABRICATING THE SAME

(71) Applicant: Samsung Display Co., Ltd., Yongin-Si (KR)

(72) Inventors: Hee Ju WOO, Yongin-si (KR); Ki Yong KIM, Yongin-si (KR); Cho Long WON, Yongin-si (KR); Hyung Bin CHO, Yongin-si (KR); Kyung Bin CHOI, Yongin-si (KR)

(21) Appl. No.: 19/097,877

(22) Filed: Apr. 2, 2025

(30) Foreign Application Priority Data
Sep. 23, 2024 (KR) 10-2024-0128063

(51) Int. Cl. H10K 59/131; H10K 59/12

(52) U.S. Cl. CPC H10K 59/1315; H10K 59/1201

(57) ABSTRACT

A display device includes a display panel, and a driver circuit connected to a pad of the display panel. The driver circuit may include a terminal connection electrode, a terminal disposed on the terminal connection electrode and connected to the pad, and a particle disposed between the terminal connection electrode and the terminal. The terminal may include a first terminal electrode on the particle and a second terminal electrode on the first terminal electrode.

### CROSS-REFERENCE TO RELATED APPLICATION

This application claims priority to Korean Patent Application No. 10-2024-0128063, filed on Sep. 23, 2024, in the Korean Intellectual Property Office, the entire contents of which are incorporated herein by reference.

### BACKGROUND

### 1. Field

The present disclosure relates to a display device in which contact resistance between a display panel and a driver circuit can be minimized, an electronic device and a method of fabricating the display device.

### 2. Description of the Related Art

Organic light emitting diode displays have self-luminous characteristics and, unlike liquid crystal displays, do not require a separate light source, leading to the reduction in thickness and weight. In addition, organic light emitting diode displays have gained attention as next-generation displays for televisions, monitors, and portable electronic devices due to their high-quality characteristics such as low power consumption, high luminance, and high response speed.

### SUMMARY

Aspects of the present disclosure provide a display device in which contact resistance between a display panel and a driver circuit can be minimized.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment, a display device includes a display panel, and a driver circuit connected to a pad of the display panel. The driver circuit may include a terminal connection electrode, a terminal disposed on the terminal connection electrode and connected to the pad, and a particle disposed between the terminal connection electrode and the terminal. The terminal may include a first terminal electrode on the particle and a second terminal electrode on the first terminal electrode.

The particle may have a spherical shape.

The particle may comprise polymer.

The particle may have a diameter ranging from 0.5 to 1.0 [symbol] .

The particle may have a hardness ranging from 5 to 10 GPa.

The display device may further include a protruding pattern between the pad and a pad connection electrode of the display panel.

The hardness of the particle may be different from a hardness of the protruding pattern.

The hardness of the particle may be greater than the hardness of the protruding pattern.

The terminal may contact the pad on the protruding pattern.

The terminal may penetrate at least one pad electrode included in the pad on the protruding pattern.

The pad may include a plurality of pad electrodes, and the terminal may penetrate at least one of the pad electrodes.

The pad may include a first pad electrode on the pad connection electrode, a second pad electrode on the first pad electrode, and a third pad electrode on the second pad electrode.

The second terminal electrode may penetrate the third pad electrode to contact the second pad electrode.

The second terminal electrode may include gold, the third pad electrode may include titanium, and the second pad electrode may include aluminum.

The particle may include a core, and an insulating layer surrounding the core.

The core may include polymer.

A surface of the terminal which faces the pad may have a hemispherical shape.

According to an embodiment, a method of fabricating a display device includes forming a first insulating layer on a substrate of a driver circuit, forming a terminal connection electrode on the first insulating layer, forming a second insulating layer on the terminal connection electrode, forming a terminal contact hole exposing the terminal connection electrode on the second insulating layer, placing a particle on the terminal connection electrode, forming a terminal on the particle, and connecting the terminal of the driver circuit to a pad of a display panel.

According to an embodiment, an electronic device includes a display device including a screen. The display device may include a display panel, and a driver circuit connected to a pad of the display panel, and the driver circuit may include a terminal connection electrode, a terminal disposed on the terminal connection electrode and connected to the pad, and a particle disposed between the terminal connection electrode and the terminal. The terminal may include a first terminal electrode on the particle and a second terminal electrode on the first terminal electrode.

The effects of the present disclosure are not limited to the above-described effects and other effects which are not described herein will become apparent to those skilled in the art from the following description.

### BRIEF DESCRIPTION OF THE DRAWINGS

The above and other features of the present disclosure will become apparent and more readily appreciated from the following description of the embodiments, taken in conjunction with the accompanying drawings.

FIG. 1 is a plan view of a display device according to an embodiment.

FIG. 2 is a plan view of the display device without a driver circuit, a first circuit board, and a second circuit board of FIG. 1.

FIG. 3 is an enlarged view of area A1 of FIG. 2.

FIG. 4 is a cross-sectional view taken along a line I-I′ of FIG. 3.

FIG. 5 is an enlarged view of area A2 of FIG. 4.

FIG. 6 is a cross-sectional view of a particle of FIG. 5.

FIG. 7 is a cross-sectional view of a display device according to an embodiment.

FIGS. 8 through 12 are process diagrams explaining a method of fabricating a driver circuit of a display device according to an embodiment.

FIG. 13 is a block diagram of an electronic device according to an embodiment.

FIGS. 14, 15 and 16 are schematic diagrams of electronic devices according to various embodiments.

### DETAILED DESCRIPTION

The present invention will now be described more fully hereinafter with reference to the accompanying drawings, in which embodiments of the present disclosure are shown. However, the present disclosure is not limited to the embodiments disclosed herein but may be implemented in various different ways. These embodiments are merely provided to ensure the full disclosure of the present inventive concept and to completely convey the scope of the present disclosure to those skilled in the art. It is to be noted that the scope of the present disclosure is defined only by the claims.

It will also be understood that when a layer is referred to as being “on” another layer or substrate, it can be directly on the other layer or substrate, or intervening layers may also be present. The same reference numbers indicate the same components throughout the specification. In the drawings, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of the present disclosure.

Each of the features of the various embodiments of the present disclosure may be partially or entirely combined with each other and technically interwork with each other in various ways. Each embodiment may be implemented independently from each other or may be implemented together in association with each other.

Hereinafter, embodiments will be described in detail with reference to the accompanying drawings.

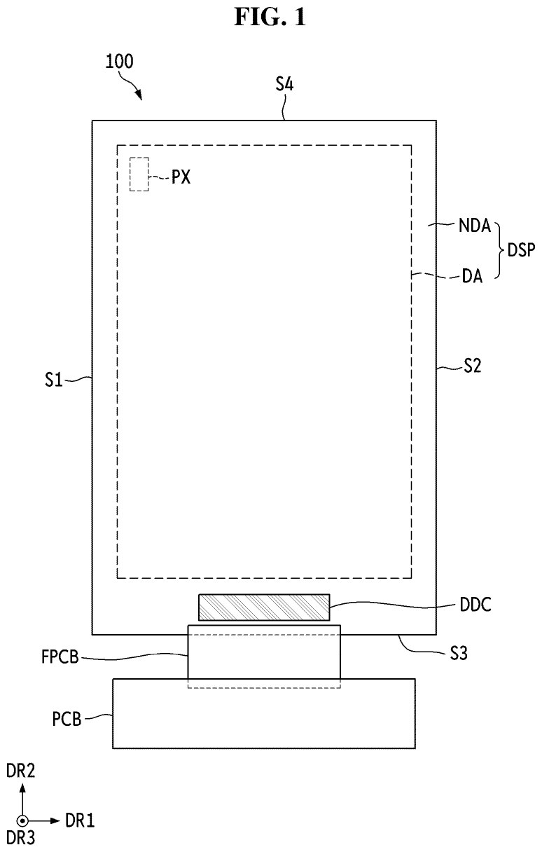

FIG. 1 is a plan view of a display device 100 according to an embodiment.

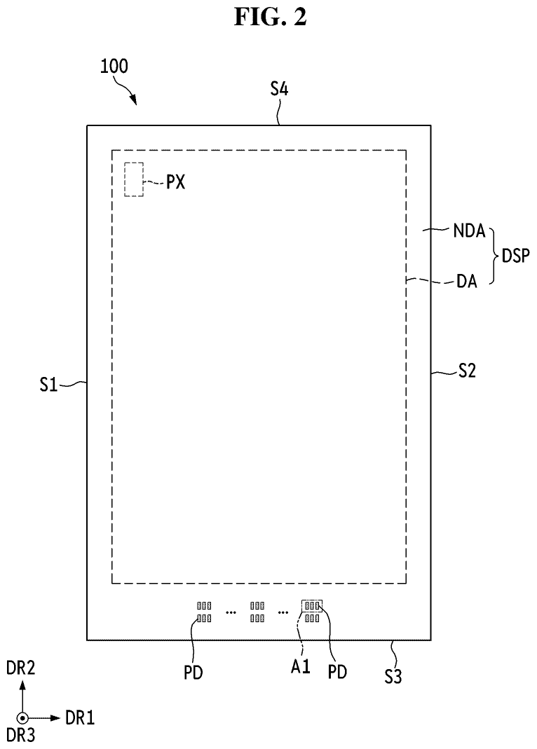

FIG. 2 is a plan view of the display device 100 without a driver circuit DDC, a first circuit board FPCB, and a second circuit board PCB of FIG. 1.

Referring to FIG. 1, the display device 100 is a device for displaying moving images or still images. The display device 100 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices. These are presented only as examples, and the display device 100 of the present disclosure can also be employed in other electronic devices.

The display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode. However, the present disclosure is not limited thereto. For example, the display device 100 may also be a display device of a type other than a light emitting display device. Embodiments in which the display device 100 is a light emitting display device (e.g., an organic light emitting display device) will be disclosed below.

The display device 100 may include a display panel DSP, the first circuit board FPCB, the second circuit board PCB, and the driver circuit DDC (e.g., a data driver circuit).

The display panel DSP may be provided as a rigid panel that is substantially not deformed or may be provided as a flexible panel that can be deformed, for example, can be folded, bent, or rolled in at least a portion. The display panel DSP may be provided to the display device 100 in an unbent state or may be provided to the display device 100 in a bent state at least in part.

The display panel DSP may include a display area DA and a non-display area NDA.

A plurality of pixels PX may be disposed in the display area DA. The pixels PX may display an image. In addition, a plurality of gate lines and a plurality of emission lines connected to the pixels PX may be disposed in the display area DA. The display area DA may have various shapes according to embodiments. For example, the display area DA may have a quadrilateral shape, a polygonal shape other than the quadrilateral shape, a circular shape, an oval shape, an irregular shape, or other shapes. In an embodiment, the display area DA may have a shape that corresponds to the shape of the display panel DSP.

The non-display area NDA may be disposed around the display area DA. In an embodiment, the non-display area NDA may surround the display area DA. A gate driver and an emission driver for driving the pixels PX may be disposed in the non-display area NDA of the display panel DSP. The gate driver may be connected to the gate lines, and the emission driver may be connected to the emission lines. Gate signals from the gate driver may be supplied to the pixels PX through the gate lines, and emission signals from the emission driver may be supplied to the pixels PX through the emission lines.

A first side S1 and a second side S2 of the display panel DSP may face each other in a first direction DR1, and a third side S3 and a fourth side S4 of the display panel DSP may face each other in a second direction DR2. The first circuit board FPCB may overlap the third side S3. Here, the first side S1 (or the second side S2) may have a longer length than the third side S3 (or the fourth side S4). However, the present disclosure is not limited thereto, and the length of each of the first side S1, the second side S2, the third side S3, and the fourth side S4 can be variously modified.

The driver circuit DDC may be connected to the display panel DSP. For example, the driver circuit DDC may be electrically connected to the non-display area NDA of the display panel DSP. The driver circuit DDC may include, for example, an integrated circuit.

The first circuit board FPCB may be connected to the display panel DSP and the second circuit board PCB. For example, a side of the first circuit board FPCB may be electrically connected to the non-display area NDA of the display panel DSP, and the other side of the first circuit board FPCB may be electrically connected to the second circuit board PCB. The first circuit board FPCB may be, but is not limited to, a flexible film such as a flexible printed circuit board or a printed circuit board. For example, the first circuit board FPCB may be a flexible printed circuit board.

The second circuit board PCB may be electrically connected to the display panel DSP through the first circuit board FPCB and may exchange signals with the driver circuit DDC. The second circuit board PCB may provide image data, control signals, power voltages, etc. to the display panel DSP or the first circuit board FPCB. Active and passive elements may be disposed on the second circuit board PCB. For example, a timing controller and a power supply unit may be disposed on the second circuit board PCB. The second circuit board PCB may be either a flexible printed circuit board or a rigid printed circuit board. For example, the second circuit board PCB may be a rigid printed circuit board.

The power supply unit may supply power voltages to the pixels PX, the gate driver, the emission driver, and the data driver circuit DDC. The timing controller may control the operations of the gate driver, the emission driver, and the data driver circuit DDC.

Through the first circuit board FPCB, a gate timing control signal, an emission timing control signal, a gate clock signal, an emission clock signal, a gate start signal, an emission start signal, a high-potential voltage, or a low-potential voltage from the timing controller disposed on the second circuit board PCB may be supplied to the gate driver or the emission driver accordingly. For example, the gate timing control signal, the gate clock signal, the gate start signal, the high-potential voltage and the low-potential voltage may be supplied to the gate driver, and the emission timing control signal, the emission clock signal, the emission start signal, the high-potential voltage and the low-potential voltage may be supplied to the emission driver. In addition, power signals from the power supply unit disposed on the second circuit board PCB may be supplied to the gate driver, the emission driver, and the pixels PX through the first circuit board FPCB. The power signals may include, for example, a driving voltage, a common voltage, an initialization voltage, and a bias voltage.

As illustrated in FIG. 2, a plurality of pads PD may be disposed in the non-display area NDA of the display panel DSP. For example, the pads PD may be disposed close to an edge (e.g., the third side S3) of the display panel DSP. Here, the pads PD may be arranged along the third side S3. For example, the pads PD may be arranged along the first direction DR1.

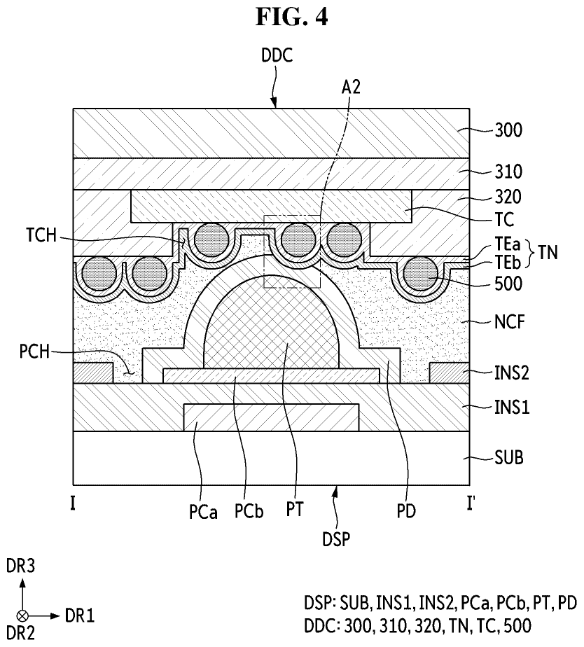

The pads PD of the display panel DSP may be connected to a plurality of terminals (or bumps) (e.g., TN of FIG. 4) of the driver circuit DDC. Among the pads PD of FIG. 2, pads (e.g., input pads) disposed closer to the third side S3 may transmit signals from the first circuit board FPCB and the second circuit board PCB to the driver circuit DDC. Among the pads PD of FIG. 2, pads (e.g., output pads) disposed closer to the display area DA may transmit signals from the driver circuit DDC to the pixels PX of the display area DA.

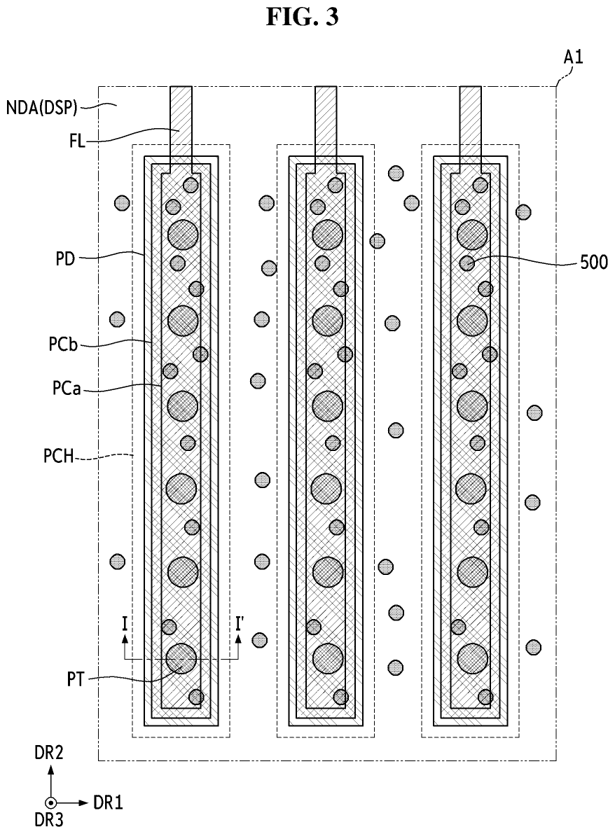

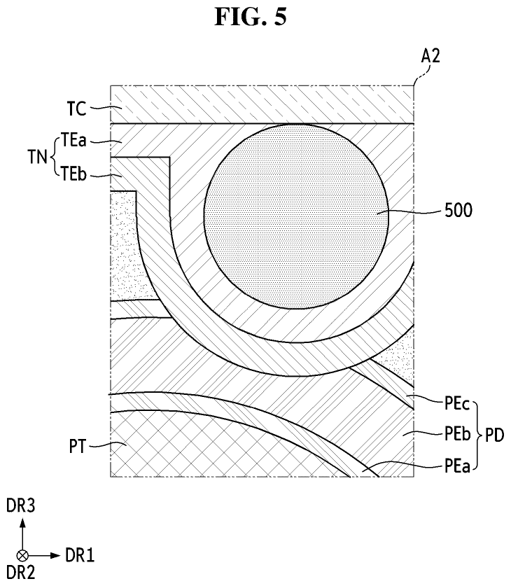

FIG. 3 is an enlarged view of area A1 of FIG. 2. FIG. 4 is a cross-sectional view taken along a line I-I′ of FIG. 3. FIG. 5 is an enlarged view of area A2 of FIG. 4.

First pad connection electrodes PCa may be disposed on a substrate SUB of the display panel DSP. Each of the first pad connection electrodes PCa may include a conductive material including molybdenum (Mo), aluminum (Al), copper (Cu), titanium (Ti), etc. and may be formed as a multilayer or single layer including the above materials. A first insulating layer INS1 may be disposed on the first pad connection electrodes PCa.

Second pad connection electrodes PCb may be disposed on the first insulating layer INS1 to overlap the first pad connection electrodes PCa. The second pad connection electrodes PCb may be connected to the first pad connection electrodes PCa. To this end, an extension portion of each of the second pad connection electrodes PCb, which extends toward the display area DA, may be connected to a fan-out line FL through a contact hole penetrating the first insulating layer INS1. Fan-out lines FL may be formed integrally with the first pad connection electrodes PCa. Each of the second pad connection electrodes PCb may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may be a single layer or multilayer of the above materials.

A second insulating layer INS2 may be disposed on the second pad connection electrodes PCb. The second insulating layer INS2 may contact (or directly contact) the second pad connection electrodes PCb. The second insulating layer INS2 may have pad contact holes PCH.

Protruding patterns PT may be disposed on each of the second pad connection electrodes PCb. For example, the protruding patterns PT may be disposed on each of the second pad connection electrodes PCb within a pad contact hole PCH. The protruding patterns PT may contact (or directly contact) each of the second pad connection electrodes PCb. The protruding patterns PT may have a hemispherical shape. For example, the protruding patterns PT may have a circular shape in plan view as illustrated in FIG. 3. In addition, the protruding patterns PT may have a semicircular shape in cross sectional view, as illustrated in FIG. 4. For example, in cross sectional view, the protruding patterns PT may have a parabolic or lens shape that protrudes convexly toward the driver circuit DDC. However, the present disclosure is not limited thereto, and the protruding patterns PT may also have various shapes such as a circle and a triangle in plan view. The protruding patterns PT may include a polymer-based material. Examples of the polymer-based material may include acrylic resin, epoxy resin, polyimide, and polyethylene.

The pads PD may be disposed on the second insulating layer INS2, the protruding patterns PT, and the second pad connection electrodes PCb. The pads PD may contact (or directly contact) the second insulating layer INS2, the protruding patterns PT, and the second pad connection electrodes PCb. The pads PD may be connected to the fan-out lines FL. For example, the pads PD may be connected to the fan-out lines FL through the second pad connection electrodes PCb and the first pad connection electrodes PCa. The fan-out lines FL may be connected to, for example, data lines. Each of the pads PD may include a conductive material including molybdenum (Mo), aluminum (Al), copper (Cu), titanium (Ti), etc. and may be formed as a multilayer or single layer including the above materials. For example, as illustrated in FIG. 5, each of the pads PD may have a multilayer structure including a first pad electrode PEa containing titanium, a second pad electrode PEb containing aluminum, and a third pad electrode PEc containing titanium. Here, the second pad electrode PEb may be disposed between the first pad electrode PEa and the third pad electrode PEc.

Since the protruding patterns PT are arranged along a longitudinal direction (e.g., the second direction DR2) of each pad PD, each pad PD on the protruding patterns PT may have an uneven shape. For example, each of the pads PD may have a protruded convex portion along a third direction DR3 and a recessed concave portion along a reverse direction (hereinafter, referred to as a third reverse direction) of the third direction DR3. Specifically, a first portion of each pad PD disposed on the protruding patterns PT may be protruded in the third direction DR3, and a second portion of each pad PD disposed between adjacent protruding patterns PT may be recessed in the third reverse direction. Here, the first portion of each pads PD protruding in the third direction DR3 may contact (or directly contact) terminals TN of the driver circuit DDC. Through this contact, the pads PD of the display panel DSP and the terminals TN of the driver circuit DDC may be electrically connected.

As illustrated in FIG. 4, the driver circuit DDC may be disposed on the pads PD of the display panel DSP.

The driver circuit DDC may include a substrate 300, a first insulating layer 310, a second insulating layer 320, particles 500 and the terminals TN. Here, each of the terminals TN may include a first terminal electrode TEa and a second terminal electrode TEb.

A plurality of transistors (or chips) may be disposed on the substrate 300. The substrate 300 may include, for example, a wafer.

The first insulating layer 310 may be disposed on the substrate 300. The first insulating layer 310 may include silicon nitride (SiNₓ).

The terminal connection electrode TC may be disposed on the first insulating layer 310. The terminal connection electrode TC may be connected to a transistor on the substrate 300. For example, the terminal connection electrode TC may be connected to the transistor on the substrate 300 through a contact hole penetrating the first insulating layer 310.

The second insulating layer 320 may be disposed on the terminal connection electrode TC and the first insulating layer 310. The second insulating layer 320 may have a terminal contact hole TCH that extends to the terminal connection electrode TC.

The terminal TN may be disposed on the second insulating layer 320 and the terminal connection electrode TC. The terminal TN may be connected to the terminal connection electrode TC through the terminal contact hole TCH of the second insulating layer 320. The terminal TN may be formed as a multilayer. For example, the terminal TN may include a first terminal electrode TEa and a second terminal electrode TEb.

The first terminal electrode TEa may be disposed on the second insulating layer 320 and the terminal connection electrode TC. The first terminal electrode TEa may be connected to the terminal connection electrode TC through the terminal contact hole TCH of the second insulating layer 320. The first terminal electrode TEa may include titanium (Ti).

The second terminal electrode TEb may be disposed on the first terminal electrode TEa. The second terminal electrode TEb and the first terminal electrode TEa may contact (or directly contact) each other. The second terminal electrode TEb may include gold (Au).

The particles 500 may be disposed between the terminal connection electrode TC and the terminal TN. For example, the particles 500 may be disposed between the terminal connection electrode TC and the first terminal electrode TEa. A plurality of particles 500 overlapping any one terminal TN may overlap 30% or more of the total area of the terminal TN.

At least one of the particles 500 may be surrounded by the terminal TN. For example, at least one of the particles 500 may be surrounded by the first terminal electrode TEa.

At least one of the particles 500 may contact (or directly contact) the terminal TN. For example, at least one of the particles 500 may contact (or directly contact) the first terminal electrode TEa.

At least one of the particles 500 may contact (or directly contact) the terminal connection electrode TC.

At least one of the particles 500 may contact (or directly contact) the second insulating layer 320.

The particles 500 may have a spherical shape. However, the present disclosure is not limited thereto, and the particles 500 may also be changed into various shapes such as a polyhedron.

The particles 500 may include a polymer-based material. Examples of the polymer-based material may include acrylic resin, epoxy resin, polyimide, and polyethylene. For example, the particles 500 may be insulators.

Since the particles 500 are disposed between the terminal connection electrode TC and the terminal TN, the terminal TN may have an irregular shape following the shape of the particles 500. For example, a surface of the terminal TN which faces a pad PD may have a convex portion, for example, in hemispherical shape, that protrudes toward the pad PD. On the other hand, the terminal TN may have a recessed concave portion between the particles 500. As a result, the surface of the terminal TN may have an uneven shape. In an embodiment, the protruded portion of the terminal TN may have a hemispherical shape.

A non-conductive film NCF may be disposed between the display panel DSP and the driver circuit DDC. For example, the non-conductive film NCF may be disposed between the pads PD and the terminals TN. The display panel DSP and the driver circuit DDC may be bonded to each other by the non-conductive film NCF. The non-conductive film NCF may include a material such as resin.

As described above, a terminal TN may have a plurality of convex portions protruding toward a pad PD due to the particles 500. Therefore, a contact area between the terminal TN and the pad PD can be improved. For example, according to an embodiment, a terminal TN having a plurality of convex portions in hemispherical shapes may surround a pad PD (e.g., a pad PD on the protruding patterns PT) to contact the pad PD. Therefore, the contact area between the terminal TN and the pad PD can be improved. Accordingly, contact resistance between the terminal TN and the pad PD can be minimized.

In addition, since a surface of a terminal TN has a plurality of convex portions in hemispherical shapes, the terminal TN may penetrate some layers of a pad PD (e.g., a pad PD on the protruding patterns PT). For example, as illustrated in FIG. 5, a terminal TN may penetrate an outermost pad electrode (e.g., the third pad electrode PEc) of a pad PD and contact (or directly contact) the second pad electrode PEb under the outermost pad electrode. In this case, metals having excellent electrical conductivity (e.g., the second terminal electrode TEb including gold (Au) and the second pad electrode PEb including aluminum (Al)) may contact (or directly contact) each other. Therefore, the contact resistance between the terminal TN and the pad PD can be further minimized.

In addition, since the surface of a terminal TN has a plurality of convex portions in hemispherical shapes protruding toward a pad PD, a gap between the display panel DSP and the driver circuit DDC can be maintained. Accordingly, the fluidity of the non-conductive film NCF is secured, thereby improving the adhesion between the display panel DSP and the driver circuit DDC.

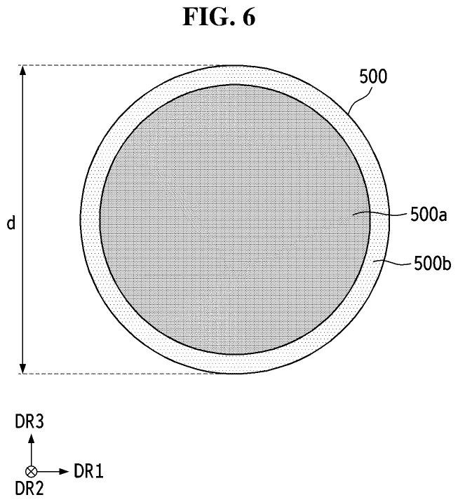

FIG. 6 is a cross-sectional view of a particle 500 of FIG. 5.

As illustrated in FIG. 6, the particle 500 may include a core 500a and an insulating layer 500b.

The core 500a may be surrounded by the insulating layer 500b. The core 500a may include a polymer-based material. Examples of the polymer-based material may include acrylic resin, epoxy resin, polyimide, and polyethylene.

The insulating layer 500b may surround the core 500a. The insulating layer 500b may include silicon nitride (SiNₓ).

The particle 500 described above may have a diameter d ranging, for example, from 0.5 to 1.0 [symbol] .

The particle 500 described above may have a high hardness ranging, for example, from 5 to 10 GPa.

According to an embodiment, the hardness of the particle 500 may be different from the hardness of a protruding pattern PT. For example, the hardness of the particle 500 may be greater than the hardness of the protruding pattern PT.

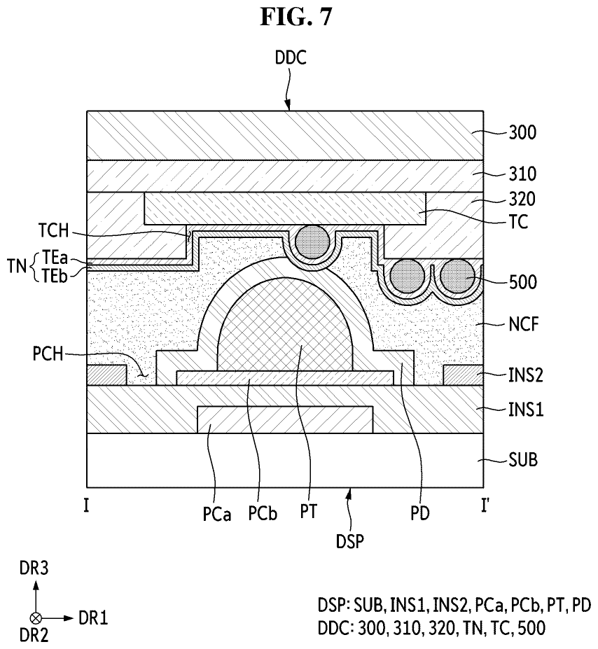

FIG. 7 is a cross-sectional view of a display device 100 according to an embodiment. For example, FIG. 7 may be a cross-sectional view of an embodiment taken along a line I-I′ of FIG. 3.

The display device 100 of FIG. 7 is different from the display device 100 of FIG. 4 described above in a contact area between a terminal TN and a pad PD. Therefore, this difference will be mainly described as follows.

As illustrated in FIG. 7, the terminal TN and the pad PD may contact each other at a single location. For example, depending on the distribution of particles 500, the contact area between the terminal TN and the pad PD may vary, as illustrated in FIGS. 4 and 7. In other words, when a plurality of pads PD of a display panel DSP are defined as a first pad and a second pad, respectively, and a plurality of terminals TN of a driver circuit DDC are defined as a first terminal and a second terminal, respectively, the distribution of the particles 500 disposed between the first terminal and the first pad connected to each other and the distribution of the particles 500 disposed between the second terminal and the second pad connected to each other may be different. Accordingly, a contact area between the first terminal and the first pad and a contact area between the second terminal and the second pad may be different.

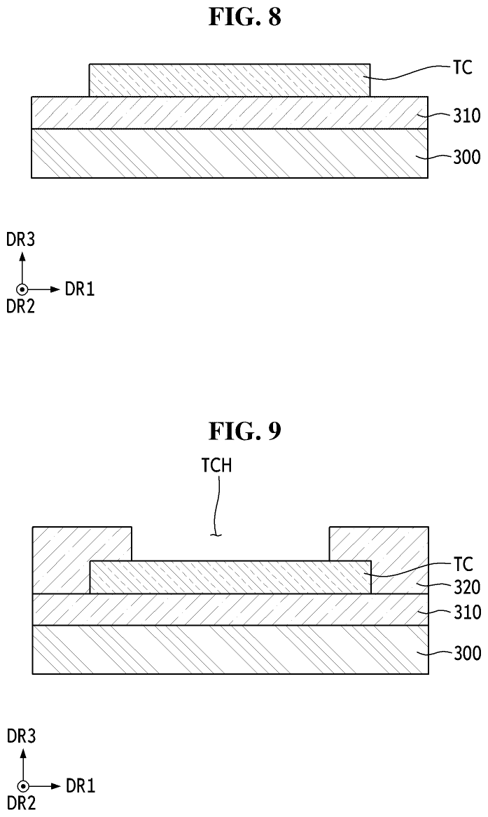

FIGS. 8 through 12 are process diagrams explaining a method of fabricating a driver circuit DDC of a display device 100 according to an embodiment.

First, as illustrated in FIG. 8, a first insulating layer 310 may be formed on a substrate 300, and then a terminal connection electrode TC may be formed on the first insulating layer 310. At this time, the substrate 300 may be placed upside down so that a surface of the substrate 300 on which the first insulating layer 310 and the terminal connection electrode TC are formed faces the third direction DR3. Here, the reverse direction of the third direction DR3 may coincide with the direction of gravity.

Next, as illustrated in FIG. 9, a second insulating layer 320 may be formed on the terminal connection electrode TC. Then, a terminal contact hole TCH exposing a portion of the terminal connection electrode TC may be formed. The terminal contact hole TCH may penetrate the second insulating layer 320 to extend to a portion of the terminal connection electrode TC.

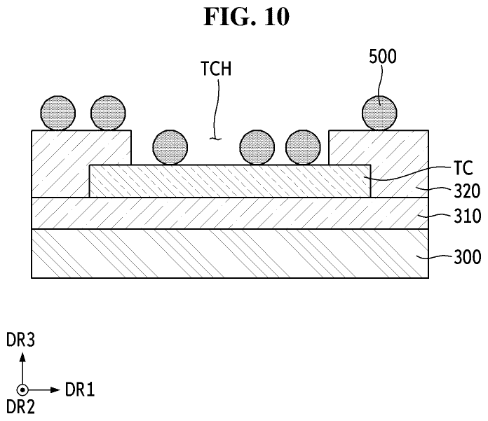

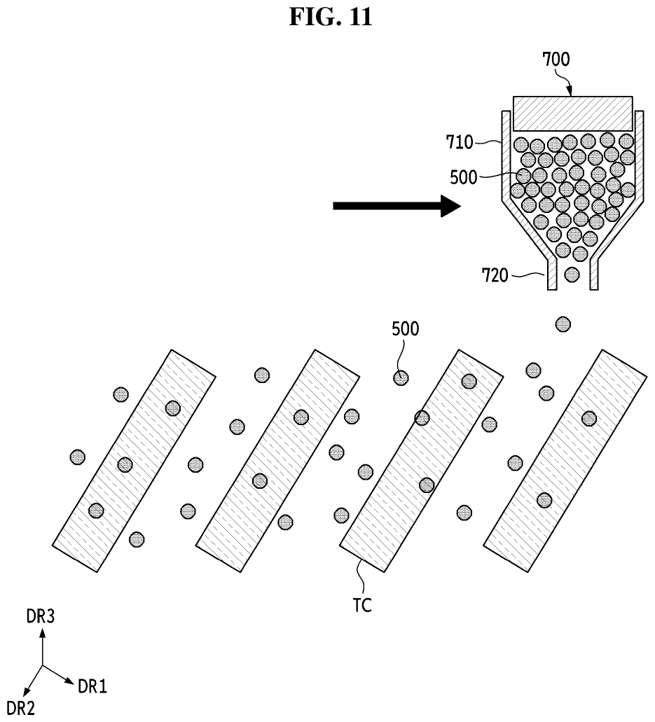

Next, as illustrated in FIG. 10, a plurality of particles 500 may be formed on the terminal connection electrode TC. For example, as illustrated in FIG. 11, the particles 500 may be provided by a dispenser 700.

The dispenser 700 may include a storage container 710 in which the particles 500 are stored and a nozzle 720 disposed at an end of the storage container 710. The dispenser 700 may discharge the particles 500 while moving along the arrow of FIG. 11 over the terminal connection electrodes TC. For example, the dispenser 700 may discharge (or spray) the particles 500 in the storage container 710 to the outside through the nozzle 720. Accordingly, the particles 500 discharged from the dispenser 700 may be randomly placed on the terminal connection electrodes TC. At this time, the particles 500 from the dispenser 700 may be placed not only on the terminal connection electrodes TC but also on the second insulating layer 320.

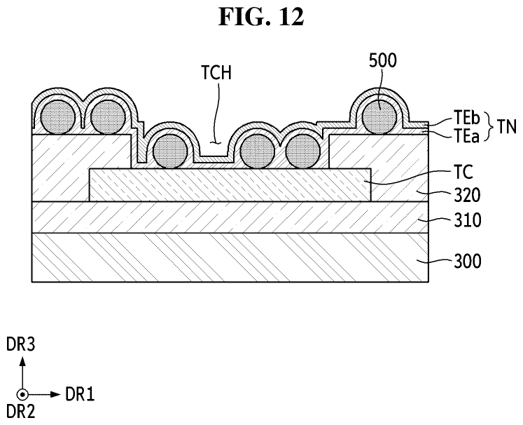

Next, as illustrated in FIG. 12, a terminal TN may be formed on the particles 500. For example, after a first terminal electrode TEa is formed on the particles 500, a second terminal electrode TEb may be formed on the first terminal electrode TEa. The movement of the particles 500 may be prevented by the terminal TN. Accordingly, the particles 500 may be positioned and fixed between the terminal connection electrode TC and the terminal TN, as well as between the terminal connection electrode TC and the second insulating layer 320.

Since the particles 500 are placed between the terminal connection electrode TC and the terminal TN as described above, the terminal TN may have an irregular shape following the shape of the particles 500. For example, a surface of the terminal TN which faces a pad PD may have a plurality of convex portions, for example, in hemispherical shapes that protrude toward the pad PD. On the other hand, the terminal TN may have a recessed concave portion between the particles 500. As a result, the surface of the terminal TN may have an uneven shape. In an embodiment, the convex portions of the terminal TN may have a hemispherical shape.

The driver circuit DDC fabricated as described above may be attached to a display panel DSP. For example, after a non-conductive film NCF is formed on pads PD of the display panel DSP, the driver circuit DDC may be aligned on the display panel DSP such that terminals TN of the driver circuit DDC overlap the pads PD of the display panel DSP. Then, the driver circuit DDC may be pressed to bond the driver circuit DDC and the display panel DSP to each other. Accordingly, the terminals TN of the driver circuit DDC and the pads PD of the display panel DSP may be electrically connected to each other. As a result, the display device 100 may be fabricated.

According to a display device of an embodiment, contact resistance between a display panel and a driving circuit can be minimized.

For example, as a terminal may have a plurality of convex portions in hemispherical shapes protruding toward a pad due to a plurality of particles, a contact area between the terminal and the pad can be improved. For example, according to an embodiment, as the terminal having a plurality of convex portions in hemispherical shapes may surround the pad to contact the pad, the contact area between the terminal and the pad can be improved. Accordingly, contact resistance between the terminal and the pad can be minimized.

The display device according to the embodiment can be applied to various electronic devices. The electronic device according to an embodiment includes the display device described above and may further include modules or devices having additional functions in addition to the display device.

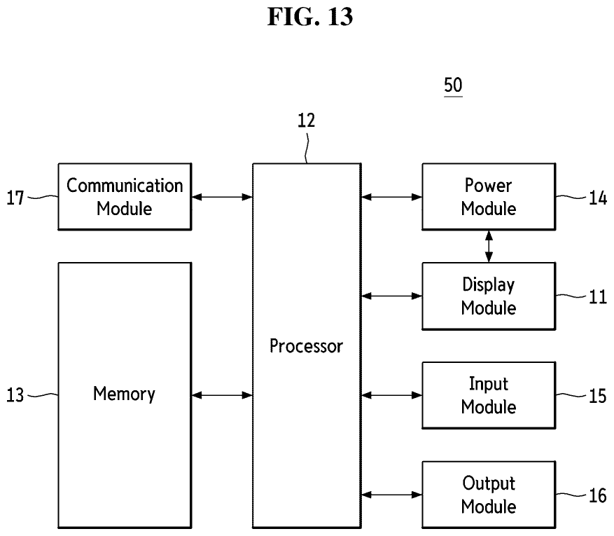

FIG. 13 is a block diagram of an electronic device according to an embodiment. Referring to FIG. 13, the electronic device 50 according to an embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, while the display device includes a display module 11 and the processor 12, memory 13 and power module 14 may be provided in the form of other devices within the electronic device 11 other than the display device.

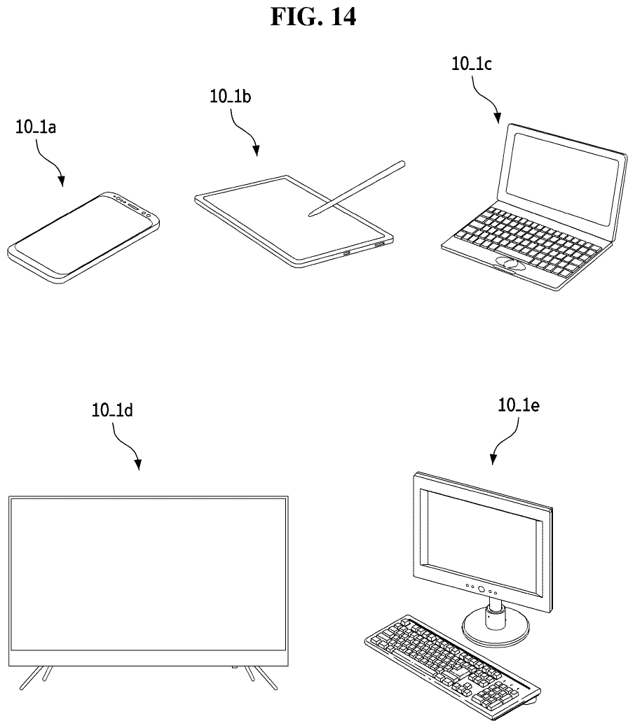

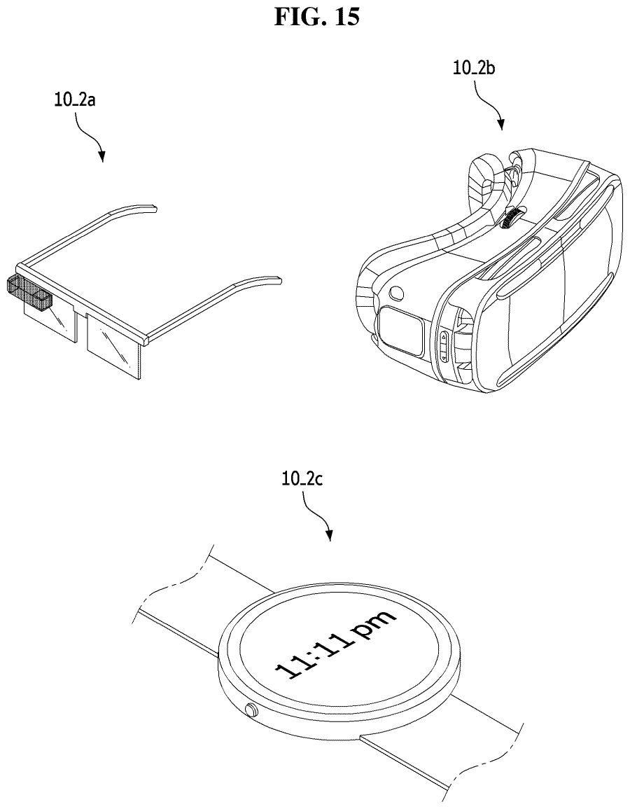

FIGS. 14, 15, and 16 are schematic diagrams of electronic devices according to various embodiments. FIGS. 14 to 16 illustrate examples of various electronic devices to which the display device according to the embodiments is applied.

FIG. 14 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

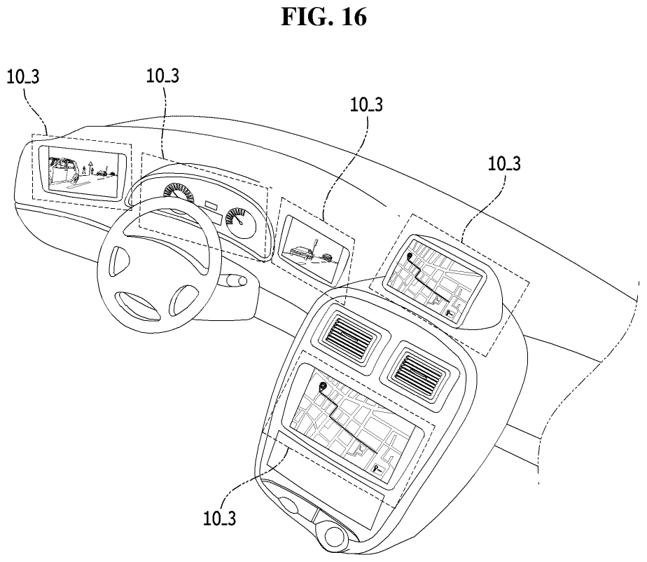

FIG. 15 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user. The smart watch 10_2c includes a biometric sensor as an input device, and may provide biometric information recognized by the biometric sensor to the user through the display module.

FIG. 16 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in various forms without changing the technical spirit or essential features of the present disclosure. Therefore, it is to be understood that the embodiments described above are illustrative and are not to be construed as limiting thereof. It is to be understood that the scope of the present disclosure are defined by the claims rather than the detailed description described above, and all modifications and alterations derived from the claims and their equivalents fall within the scope of the present disclosure.

What is claimed is:

1. A display device comprising:
a display panel; and
a driver circuit connected to a pad of the display panel,
wherein the driver circuit comprises:
a terminal connection electrode;
a terminal disposed on the terminal connection electrode and connected to the pad; and
a particle disposed between the terminal connection electrode and the terminal, and
wherein the terminal includes a first terminal electrode on the particle and a second terminal electrode on the first terminal electrode.

2. The display device of claim 1, wherein the particle has a spherical shape.

3. The display device of claim 1, wherein the particle comprises polymer.

4. The display device of claim 1, wherein the particle has a diameter ranging from 0.5 to 1.0 [symbol] .

5. The display device of claim 1, wherein the particle has a hardness ranging from 5 to 10 GPa.

6. The display device of claim 1, further comprising a protruding pattern between the pad and a pad connection electrode of the display panel.

7. The display device of claim 6, wherein the hardness of the particle is different from a hardness of the protruding pattern.

8. The display device of claim 7, wherein the hardness of the particle is greater than the hardness of the protruding pattern.

9. The display device of claim 6, wherein the terminal contacts the pad on the protruding pattern.

10. The display device of claim 9, wherein the terminal penetrates at least one pad electrode included in the pad on the protruding pattern.

11. The display device of claim 10, wherein the pad comprises a plurality of pad electrodes, and the terminal penetrates at least one of the pad electrodes.

12. The display device of claim 10, wherein the pad comprises:
a first pad electrode on the pad connection electrode;
a second pad electrode on the first pad electrode; and
a third pad electrode on the second pad electrode.

13. The display device of claim 12, wherein the second terminal electrode penetrates the third pad electrode to contact the second pad electrode.

14. The display device of claim 13, wherein the second terminal electrode comprises gold, the third pad electrode comprises titanium, and the second pad electrode comprises aluminum.

15. The display device of claim 1, wherein the particle comprises:
a core; and
an insulating layer surrounding the core.

16. The display device of claim 15, wherein the core comprises polymer.

17. The display device of claim 1, wherein a surface of the terminal which faces the pad has a hemispherical shape.

18. A method of fabricating a display device, the method comprising:
forming a first insulating layer on a substrate of a driver circuit;
forming a terminal connection electrode on the first insulating layer;
forming a second insulating layer on the terminal connection electrode;
forming a terminal contact hole, which exposes the terminal connection electrode, on the second insulating layer;
placing a particle on the terminal connection electrode;
forming a terminal on the particle; and
connecting the terminal of the driver circuit to a pad of a display panel.

19. The method of claim 18, wherein the placing of the particle comprises spraying the particle onto the terminal connection electrode using a dispenser.

20. An electronic device comprising:
a display device including a screen,
wherein the display device comprises:
a display panel; and
a driver circuit connected to a pad of the display panel,
wherein the driver circuit comprises:
a terminal connection electrode;
a terminal disposed on the terminal connection electrode and connected to the pad; and
a particle disposed between the terminal connection electrode and the terminal, and
wherein the terminal includes a first terminal electrode on the particle and a second terminal electrode on the first terminal electrode.
